(19) United States
(12) Patent Application Publication
(10) Pub. No.: US 2010/0050393 A1
(43) Pub. Date: Mar. 4, 2010

(54) APPARATUS AND METHOD OF USE FOR AN INERT GAS REBREATHER USED IN FURNACE OPERATIONS

(75) Inventor: Roger F. Clark, Knoxville, MD (US)

Correspondence Address: CAROL WILSON;BP AMERICA INC., MAIL CODE 5 EAST, 4101 WINFIELD ROAD, WARRENVILLE, IL, 60555, US

(73) Assignee: BP Corporation North America Inc., Warrenville, IL (US)

(21) Appl. No.: 12/547,585

(22) Filed: Aug. 26, 2009

Related U.S. Application Data
(60) Provisional application No. 61/176,563, filed on May 8, 2009.
(60) Provisional application No. 61/092,186, filed on Aug. 27, 2008.

(51) Int. Cl. B01D 9/00

(52) U.S. Cl. 23/300; 422/245.1

(57) ABSTRACT

This invention relates to an apparatus and a method of use for an inert gas rebreather used in furnace operations, such as melting and/or casting high purity silicon for solar cells and solar modules. The apparatus includes a process chamber, a reservoir in fluid communication with the process chamber, and a motive force device in fluid communication with the process chamber and the reservoir. Recycling or reusing the inert gas reduces operating expenses of the casting process while maintaining low impurity levels in the cast silicon.

This application claims the benefit of U.S. Provisional Application No. 61/176,563, filed May 8, 2009 and U.S. Provisional Application No. 61/092,186, filed Aug. 27, 2008, the entirety of both are expressly incorporated herein by reference.

### BACKGROUND

1. Technical Field

This invention relates to an apparatus and a method of use for an inert gas rebreather used in furnace operations, such as melting and/or casting silicon for solar cells and solar modules.

2. Discussion of Related Art

Photovoltaic cells convert light into electric current. One of the most important features of a photovoltaic cell is its efficiency in converting light energy into electrical energy. Although photovoltaic cells can be fabricated from a variety of semiconductor materials, silicon is generally used because it is readily available at reasonable cost, and because it has a suitable balance of electrical, physical, and chemical properties for use in fabricating photovoltaic cells.

In a known procedure for the manufacture of photovoltaic cells, silicon feedstock is doped with a dopant having either a positive or negative conductivity type, melted, and then crystallized by pulling crystallized silicon out of a melt zone into ingots of monocrystalline silicon (via the Czochralski (CZ) or float zone (FZ) methods). For a FZ process, solid material is fed through a melting zone, melted upon entry into one side of the melting zone, and re-solidified on the other side of the melting zone, generally by contacting a seed crystal.

Recently, a new technique for producing monocrystalline or geometric multicrystalline material in a crucible solidification process (i.e. a cast-in-place or casting process) has been invented, as disclosed in U.S. patent application Ser. Nos.: 11/624,365 and 11/624,411, and published in U.S. Patent Application Publication Nos.: 20070169684A1 and 20070169685A1, filed Jan. 18, 2007. Casting processes for preparing multicrystalline silicon ingots are known in the art of photovoltaic technology. Briefly, in such processes, molten silicon is contained in a crucible, such as a quartz crucible, and is cooled in a controlled manner to permit the crystallization of the silicon contained therein. The block of cast crystalline silicon that results is generally cut into bricks having a cross-section that is the same as or close to the size of the wafer to be used for manufacturing a photovoltaic cell, and the bricks are sawn or otherwise cut into such wafers. Multicrystalline silicon produced in such manner is composed of crystal grains where, within the wafers made therefrom, the orientation of the grains relative to one another is effectively random. Monocrystalline or geometric multicrystalline silicon has specifically chosen grain orientations and (in the latter case) grain boundaries, and can be formed by the new casting techniques disclosed in the above-mentioned patent applications by melting in a crucible the solid silicon into liquid silicon in contact with a large seed layer that remains partially solid during the process and through which heat is extracted during solidification, all while remaining in the same crucible. As used herein, the term ‘seed layer’ refers to a crystal or group of crystals with desired crystal orientations that form a continuous layer. They can be made to conform to one side of a crucible for casting purposes.

In order to produce high quality cast ingots, several conditions should be met. Firstly, as much of the ingot as possible should have the desired crystallinity. If the ingot is intended to be monocrystalline, then the entire usable portion of the ingot should be monocrystalline, and likewise for geometric multicrystalline material. Secondly, the silicon should contain as few imperfections as possible. Imperfections can include individual impurities, agglomerates of impurities, intrinsic lattice defects and structural defects in the silicon lattice, such as dislocations and stacking faults. Many of these imperfections can cause a fast recombination of electrical charge carriers in a functioning photovoltaic cell made from crystalline silicon. This can cause a decrease in the efficiency of the cell.

Many years of development have resulted in a minimal amount of imperfections in well-grown CZ and FZ silicon. Dislocation free single crystals can be achieved by first growing a thin neck where all dislocations incorporated at the seed are allowed to grow out. The incorporation of inclusions and secondary phases (for example silicon nitride, silicon oxide or silicon carbide particles) is avoided by maintaining a counter-rotation of the seed crystal relative to the melt. Oxygen incorporation can be lessened using magnetic CZ techniques and minimized using FZ techniques as is known in the industry. Metallic impurities are generally minimized by being segregated to the tang end or left in the potscrap after the boule is brought to an end.

However, even with the above improvements in the CZ and FZ processes, there is a need and a desire to produce high purity crystalline silicon that is less expensive on a per volume basis, needs less capital investment in facilities, needs less space, and/or less complexity to operate, than known CZ and FZ processes. There is a need a desire to reduce impurities in the silicon by maintaining an inert atmosphere. There is a further need and a desire to reduce inert gas consumption and reduce operating costs of the silicon casting process.

### SUMMARY

This invention relates to an apparatus and a method of use for an inert gas rebreather used in furnace operations, such as melting and/or casting silicon for solar cells and solar modules. Providing an inert gas or atmosphere during the silicon casting process reduces impurities in the silicon and ultimately the solar cells or solar modules, such as resulting in increased efficiency. The inert gas can be reused or recycled to reduce inert gas consumption and reduce operating expenses or cost associated with the silicon casting process.

According to a first embodiment, this invention relates an apparatus for supplying an inert gas to a device suitable for melting high purity silicon. The apparatus includes a process chamber with a load lock configuration for periodic charging of feedstock materials, a reservoir in fluid communication with the process chamber, and a motive force device in fluid communication with the process chamber and the reservoir.

According to a second embodiment, this invention relates to a method of operating an inert atmosphere of a device suitable for melting high purity silicon. The method includes the step of closing and evacuating air from a process chamber with a motive force device, and the step of filling the process chamber with an inert gas from a reservoir. The method also includes the step of transferring a feedstock from the process chamber to a melting area, evacuating the inert gas from the process chamber with the motive force device, and the step of capturing the inert gas from the process chamber in the reservoir. The method also includes the step of filling the process chamber with air, and the step of opening the process chamber to receive a next batch of feedstock material.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention. In the drawings:

FIG. 1 schematically illustrates an apparatus during pump down, an according to one embodiment,

FIG. 2 schematically illustrates an apparatus during inert backfill, an according to one embodiment,

FIG. 3 schematically illustrates an apparatus during inert removal, an according to one embodiment,

FIG. 4 schematically illustrates an apparatus during air fill, an according to one embodiment,

FIG. 5 schematically illustrates an apparatus during inert fill, an according to one embodiment, and

FIG. 6 schematically illustrates a casting device, according to one embodiment.

### DETAILED DESCRIPTION

This invention relates to an apparatus and a method of use for an inert gas rebreather used in furnace operations, such as melting, refining, and/or casting silicon for solar cells and solar modules. Known practices and devices for providing inert atmospheres exhaust or waste the inert gas during each cycle, such as when opening the furnace for charging feedstock. The single use of the inert gas amounts to a significant operating expense due to the cost of the inert gas refilling the furnace volume, such as with cryogenically purified argon.

According to one embodiment, this invention may include taking the exhaust inert gas of the vacuum pump through a cold trap, a particulate filter, and/or an oxygen scavenger before pumping or filling an inflatable (expanding volume) bag, similar to an aircraft fuel bladder or suitably constructed metal foil pouch, accordion bag, and/or the like. Desirably, the atmospheric pressure storage of the inert gas volume allows reintroduction to the evacuated load vessel during the next cycle, such as after evacuating the air inside a process chamber. Additional advantages of this configuration include relatively low capital costs, low mechanical risk, while using only a moderate amount of floor space.

The inert gas rebreather of this invention can provide a simple volume recovery method to capture and reuse the inert gas exhausted during repeated vacuum and backfill cycling of a load lock chamber. A suitable inert gas may include argon, helium, nitrogen, xenon, other high temperature stable evaporated liquids, combinations of the above, and/or the like. The inert gas rebreather could be used in many industries and/or applications, that deal with repeated cycling and pump out of controlled atmospheres, such as metals processing, ceramics or composites manufacturing, semiconductor manufacturing, and/or the like.

As shown in the FIG. 1-6 and according to certain embodiments, the apparatus 10 for supplying inert gas to a melting device 12 includes a process chamber 14 in fluid communication with a reservoir 16 and a motive force device 18. The reservoir 16 desirably includes a variable volume structure 20 (inflates or deflates) and/or a bladder 22, such as increasing or decreasing in volume as shown by the corresponding arrows. The motive force device may be a vacuum pump 24. The apparatus 10 includes an oxygen scavenger 26 and a particulate filter 28. The apparatus 10 also includes an inert gas supply 30 (fresh), an air inlet 32, and an exhaust 34. The melting device 12 may include a load lock 36, such as for charging feedstock to the casting process.

FIG. 1 schematically illustrates the apparatus 10 during pump down, such as removing from the process chamber 14 air and/or inert gas when not being reused or conserved. Lines connect the process chamber 14 with the motive force device 18 and the exhaust 34, such as to atmosphere. The configuration of FIG. 1 may be useful for preparing the process chamber 14 for filling with inert gas and/or preparing the apparatus 10 for maintenance work, for example.

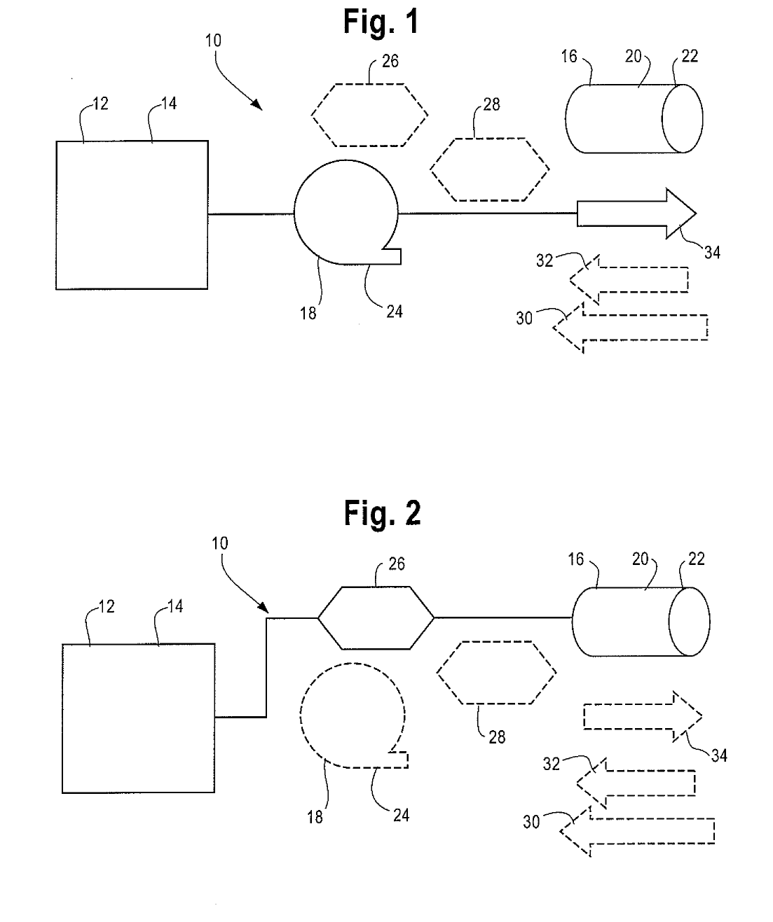

FIG. 2 schematically illustrates the apparatus 10 during inert backfill, such as supplying recycled inert gas from the reservoir 16 through the oxygen scavenger 26 and into the process chamber 14 by lines and/or tubing. FIG. 2 shows the reservoir 16 deflating as indicated by the down arrow. The configuration of FIG. 2 may be useful for recycling the inert gas to the process before melting of the silicon feedstock, such as to reduce and/or lower impurities in the finished cast silicon.

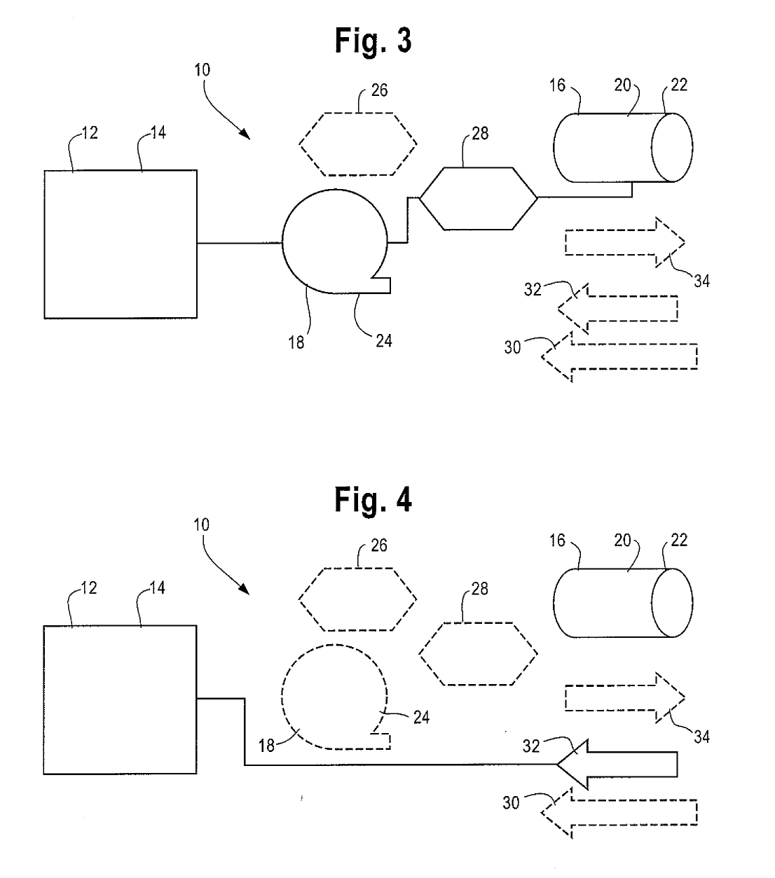

FIG. 3 schematically illustrates the apparatus 10 during inert removal, such as filling or inflating the reservoir 16 for recycling the inert gas. The inert gas flows from the process chamber 14 by lines with the aid or assistance of the motive force device 18 to flow through the particulate filter 28 and inflate the reservoir 16. The configuration of FIG. 3 may be useful for capturing the inert gas, such as to reduce operating expenses and avoid or reduce the use of make up or fresh inert gas.

FIG. 4 schematically illustrates the apparatus 10 during air fill, such as having a line connect the process chamber 14 to the air inlet 32. The configuration of FIG. 4 may be useful to prepare for opening the process to the atmosphere, such as charging feedstock.

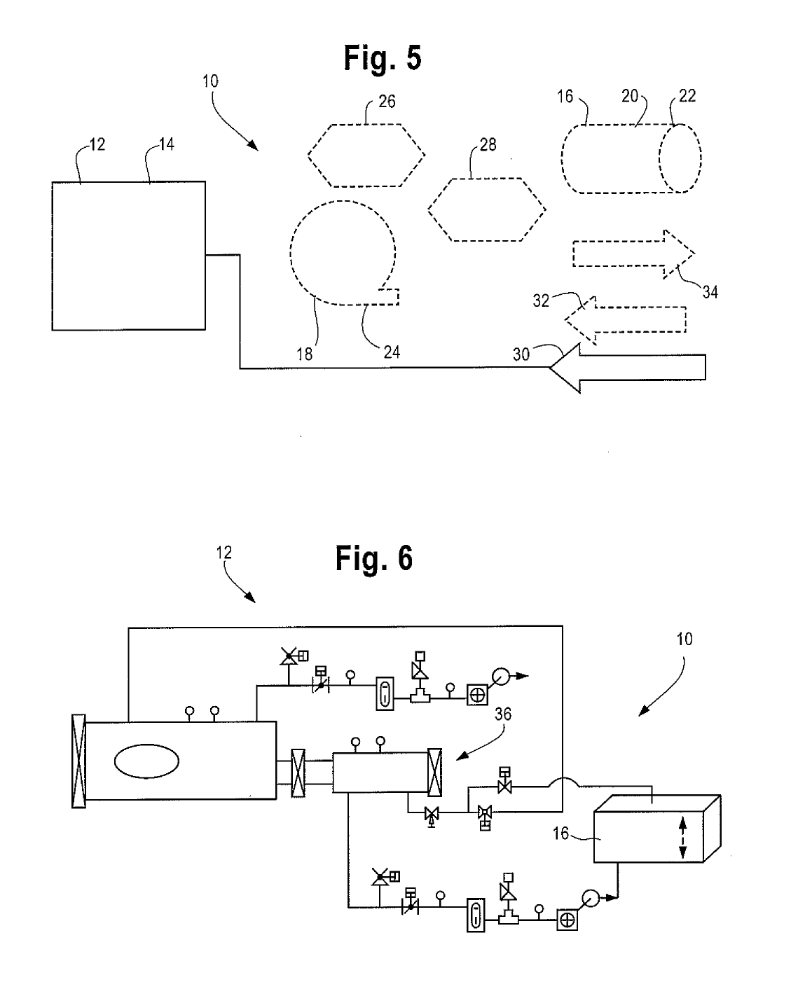

FIG. 5 schematically illustrates the apparatus 10 during inert fill, such as having a line connect the process chamber 14 to the inert gas supply 30. The configuration of FIG. 5 may be useful to prepare for heating and/or melting of feedstock, the initial fill of the process chamber 14 and reservoir 16 following maintenance procedures, and/or the like. The embodiment of FIG. 5 may prevent and/or reduce impurities in the cast and/or melted silicon, for example.

FIG. 6 schematically illustrates the apparatus 10 and casting device 12 with a load lock 36 and reservoir 16. The load lock 36 may be sometimes referred to as the charger chamber and can be used to charge or load feedstock to the meter chamber.

Moreover, although casting of silicon has been described herein, other semiconductor materials and nonmetallic crystalline materials may be cast without departing from the scope and spirit of the invention. For example, the inventors have contemplated casting of other materials consistent with embodiments of the invention, such as germanium, gallium arsenide, silicon germanium, aluminum oxide (including its single crystal form of sapphire), gallium nitride, zinc oxide, zinc sulfide, gallium indium arsenide, indium antimonide, germanium, yttrium barium oxides, lanthanide oxides, magnesium oxide, calcium oxide, and other semiconductors, oxides, and intermetallics with a liquid phase. In addition, a number of other group III-V or group II-VI materials, as well as metals and alloys, could be cast according to embodiments of the present invention.

Cast silicon includes multicrystalline silicon, near multicrystalline silicon, geometric multicrystalline silicon, and/or monocrystalline silicon. Multicrystalline silicon refers to crystalline silicon having about a centimeter scale grain size distribution, with multiple randomly oriented crystals located within a body of multicrystalline silicon.

Geometric multicrystalline silicon or geometrically ordered multicrystalline silicon refers to crystalline silicon having a nonrandom ordered centimeter scale grain size distribution, with multiple ordered crystals located within a body of multicrystalline silicon. The geometric multicrystalline may include grains typically having an average about 0.5 centimeters to about 5 centimeters in size and a grain orientation within a body of geometric multicrystalline silicon can be controlled according to predetermined orientations, such as using a combination of suitable seed crystals.

Polycrystalline silicon refers to crystalline silicon with micrometer to millimeter scale grain size and multiple grain orientations located within a given body of crystalline silicon. Polycrystalline silicon may include grains typically having an average of about submicron to about micron in size (e.g., individual grains are not visible to the naked eye) and a grain orientation distributed randomly throughout.

Monocrystalline silicon refers to crystalline silicon with very few grain boundaries since the material has generally and/or substantially the same crystal orientation. Monocrystalline material may be formed with one or more seed crystals, such as a piece of crystalline material brought in contact with liquid silicon during solidification to set the crystal growth. Near monocrystalline silicon refers to generally crystalline silicon with more grain boundaries than monocrystalline silicon but generally substantially fewer than multicrystalline silicon.

Silicon of the above described types and kinds may be cast and/or formed into blocks, ingots, bricks, wafers, any suitable shape or size, and/or the like.

The high purity silicon made with this invention may include any suitable level of reduced impurities. Impurities broadly include carbon, silicon carbide, silicon nitride, oxygen, other metals, and/or substances which generally reduce an efficiency of a solar cell or a solar module. The ingot may include a carbon concentration of about 2×10¹⁶ atoms/centimeter cubed to about 5×10¹⁷ atoms/centimeter cubed, an oxygen concentration not exceeding 7×10¹⁷ atoms/centimeter cubed, and a nitrogen concentration of at least 1×10¹⁵ atoms/centimeter cubed. Desirably, the ingot may further be substantially free from radially distributed defects, such as made without the use of rotational (spinning) processes and/or pulling.

According to one embodiment, this invention may include an apparatus for supplying an inert gas to a device suitable for melting and/or producing high purity silicon. The apparatus may include a process chamber, a reservoir in fluid communication with the process chamber, and a motive force device in fluid communication with the process chamber and the reservoir.

High purity silicon may include materials and substances that have been purified or refined to contain fewer impurities or contaminates than silica ore and/or metallurgical grade silicon. Desirably, the high purity silicon can be used to produce solar cells or solar modules, such as with an efficiency of at least about 14 percent, at least about 15 percent, at least about 16 percent, at least about 17 percent, at least about 18 percent, and/or the like. The high purity silicon may sometimes be referred to as solar grade silicon. The high purity silicon may include one or more dopants (positive or negative), such as to alter or change the electrical properties of the material.

The device for use in producing high purity silicon may include a high temperature furnace, a casting station, an individual melting device, a holding device, a purifying device, a solidifying or crystallizing device, a single device used for melting, holding, and solidifying, another suitable device, and/or the like.

The process chamber broadly includes an internal portion of the silicon processing device, such as having a volume in fluid communication with a molten silicon surface or interface. For example, the inside of a furnace with a crucible for containing molten silicon may form a process chamber. Desirably, at least a portion of the process chamber can be at least somewhat thermally isolated from the surroundings, such as by one or more layers of insulation. The process chamber by be generally at least somewhat gas or vapor tight, such as not in fluid communication with the surrounding atmosphere or environment. In the alternative, at least a portion of the process chamber may be exposed to the surrounding atmosphere, such as allowing positive pressure of the inert gas to spill out into the surroundings.

The reservoir may include any suitable place where something can be kept in store or in quantity for use. Desirably, the reservoir includes a part or a portion of an apparatus in which a gas or liquid can be held, such as an extra supply. According to one embodiment, the reservoir may include inflatable and/or collapsible materials, such as having a generally fabric like quality. The reservoir may include any suitable material, such as polyethylene, polypropylene, styrene block copolymer, polyester, nylon, natural rubber, synthetic rubber, elastomer, fluoropolymer, polyaramid, metallic foil, and/or the like. The reservoir may include woven materials, nonwoven materials, composite materials, multilayer materials, laminate materials, and/or the like.

The reservoir may include any suitable size and/or shape, such as at least about half a volume of the process chamber, at least about equal the volume of the process chamber, at least about twice the volume of the process chamber, and/or the like. The volume of the reservoir may include any suitable capacity, such as at least about 2 meters cubed, at least about 5 meters cubed, about least about 10 meters cubed, and/or the like.

The reservoir may include any suitable structure, frame, and/or support, such as to facilitate filling and/or emptying. Desirably, the reservoir may include a variable-volume structure, such as for increasing during filling and decreasing during emptying. In the alternative, the reservoir may include a generally fixed-volume structure, such as with a generally constant volume during filling or emptying. Fixed-volume structures may at least in part be fabricated according to suitable pressure vessel codes, such as for applicable pressures and/or temperatures. Combinations of variable-volume and fixed-volumes structures are within the scope of this invention.

The reservoir may operate at any suitable temperature, such as compatible with materials of construction. The reservoir may operate at ambient conditions, at above ambient conditions, at below ambient conditions, at least about 20 degrees Celsius, at least about 100 degrees Celsius, at least about 500 degrees Celsius, and/or the like.

The reservoir may operate at any suitable pressure, such as compatible with materials of construction. The reservoir may operate at full vacuum or at atmospheric pressure, balanced by the collapsible reservoir that is surrounded by ambient conditions, for example.

The reservoir may include any suitable over pressure protection device or mechanism, such as a relief valve, a rupture disk, a line of weakness (material splits apart), a hook and loop fastener seal, and/or the like. The reservoir may include any suitable instrumentation device or monitoring equipment, such as oxygen sensors, moisture sensors, explosimeters, pressure sensors, level sensors, temperature sensors, proximity switches, and/or the like.

The bladder may broadly include a receptacle of a liquid or a gas, such as something generally like a rubber bag or a plastic bag. The bladder may include an at least relatively gas impermeable material. The bladder may include a relatively inelastic (not stretchable) material. In the alternative, the bladder may include a relatively elastic (stretchable) material.

Fluidly connecting and/or in fluid communication broadly includes a liquid or a gas being able to flow, transport, and/or pass from a first location to a second location. Fluid connections may be made by any suitable manner, such as with channels, ducts, pipes, tubing, spill-ways, conduits, baffles, weirs, placing items in close proximity, and/or the like.

The motive force device broadly includes any suitable device, such as a vacuum pump, a vacuum blower, a regenerative blower, a compressor, a rotary lobe blower, an ejector, an eductor, a fan, a mechanical pump, and/or the like. The motive force device may include any suitable driver or power source, such as an alternating current motor, a direct current motor, a turbine, and/or the like. The motive force device may include any suitable oil mist separator, coalescing filter, and/or the like. The motive force device may include a vacuum breaker, a pressure relief device, any suitable device to protect the mechanical integrity of the system, and/or the like.

According to one embodiment, the apparatus may include an oxygen scavenger in a suitable location, such as in a return line between the reservoir and the process chamber. The oxygen scavenger or trap may include any suitable device and/or material to grab and/or capture oxygen that may have contaminated the recycle inert gas, such as separates the oxygen and/or oxygen containing compounds from the inert gas. Possible oxygen scavengers may include iron compounds, copper compounds, molecular sieves, zeolites, (polymer) membranes, and/or any other suitable chemical or mechanical device. Desirably, the oxygen concentration of the inert gas may include less than about 10 parts per million on a mole basis, less than about 5 parts per million on a mole basis, less than about 1 part per million on a mole basis, less than about 0.1 parts per million on mole basis, and/or the like.

The oxygen scavenger may be contained in a vessel and/or a generally cylindrical chamber, such as in a process line or tubing. In the alternative, the oxygen scavenger may be placed in the reservoir, such as in a porous or permeable pouch or bag. The oxygen scavenger may be disposable (single use) and/or regeneratable (multiple use).

According to one embodiment, the apparatus may include a particulate filter in a suitable location, such as a supply line between the reservoir and the process chamber. The particulate filter may include any suitable material to collect dust, dirt, small solid debris, silica pieces, graphite pieces, and/or the like. The particulate filter may include a porous or sintered metal. In the alternative, the particulate filter may include any other suitable filer media, such as pleated paper, polypropylene, fluoropolymer and/or the like. Desirably, the particulate filter removes particles of at least about 15 microns and larger, at least about 10 microns and larger, at least about 5 microns and larger, at least about 1 micron and larger, at least about 0.01 micron and larger, and/or the like.

The particulate filter may be contained in a vessel and/or a generally cylindrical chamber, such as in a process line or tubing. The particulate filter may be disposable (single use) and/or cleanable (multiple use).

The apparatus may include a cold trap at any suitable location, such as on a return line between the process chamber and the reservoir. The cold trap may remove and/or reduce at least a portion of water vapor and/or other condensable materials, such as having a dew point above a temperature of the cold trap. The cold trap may include dry ice and acetone (about −78 degrees Celsius), liquid nitrogen (about −196 degrees Celsius), mechanical refrigeration, and/or the like. The cold trap may allow or facilitate drawing a vacuum or reducing the pressure within the process chamber.

According to one embodiment, the apparatus may include an inert gas supply. The inert gas supply may include high pressure gas storage devices, such as tanks or cylinders. In the alternative, the inert gas supply may include a cryogenic or liquefied source, such as with a vaporizer. The inert gas supply may include a heat source, a motive force device, and/or the like. Combination devices for inert gas supply are within the scope of this invention, such as to provide redundancy or reliability.

The apparatus may include a heat exchanger and/or a suitable heat sink, such as for lowering a temperature of the inert gas. The heat exchanger may include fins or other extended surface heat transfer equipment. The heat sink may include rejecting heat or temperature to the surrounding atmosphere or environment, cooling water, refrigerant, heat transfer fluid, and/or the like. The heat exchanger may include a fan, a blower, and/or the like. In the alternative, the heat exchanger may include a peltier cooler, a thermoelectric cooler, a thermionic cooler, a solid state cooler, and/or the like.

According to one embodiment, the apparatus may include a load lock configuration, such as for charging feedstock. The load lock configuration may include one or more doors or hatches for periodic passage of additional feedstock, such as solid high purity silicon, solid metallurgical grade silicon, and/or the like.

According to one embodiment, the apparatus may include an air inlet and an exhaust. The air inlet generally allows replacement of vacuum (reduced pressure) and/or the inert gas with an atmosphere capable of sustaining normal respiration, such as about 79 percent nitrogen and about 21 percent oxygen. The air inlet may include any suitable structure, such as a pierce of tubing with an end exposed to the ambient surroundings. Desirably, the air inlet may include a valve, a solenoid, an actuated valve, and/or the like.

The exhaust generally refers to a device for removing at least a portion of the contents or atmosphere within the process chamber. The exhaust may include any suitable structure, such as a piece of tubing with an end exposed generally outside a building or a structure. In the alternative, the exhaust can be directly to the room housing the casting device. Desirably, the exhaust may include a valve, a solenoid, an actuated valve, a muffler, and/or the like.

The apparatus may also include a suitable pollution control device, such as for capturing particles from the air or gas flowing from the exhaust. The pollution control device may include a bag house, a dust collector, a smoke hog, an electrostatic precipitator, a filter media, a liquid scrubber, an oil mist separator, and/or the like.

The apparatus may also include any suitable configuration of pipes, tubes, valves, control valves, and/or the like, such as for fluid communication and configuration of the apparatus of the various components in various uses or modes of operation.

As used herein the terms “having”, “comprising”, and “including” are open and inclusive expressions. Alternately, the term “consisting” is a closed and exclusive expression. Should any ambiguity exist in construing any term in the claims or the specification, the intent of the drafter is toward open and inclusive expressions.

Regarding an order, number, sequence and/or limit of repetition for steps in a method or process, the drafter intends no implied order, number, sequence and/or limit of repetition for the steps to the scope of the invention, unless explicitly provided.

According to one embodiment, the invention may include a method of operating or providing an inert atmosphere of or to a device suitable in producing and/or melting high purity silicon. The method may include the step of closing and evacuating air from a process chamber with a motive force device, and the step of filling the process chamber with an inert gas from a reservoir. The method may also include the step of transferring a feedstock into a melting region, and the step of evacuating the inert gas from the process chamber with the motive force device. The method may also include the step of capturing the inert gas from the process chamber in the reservoir, and the step of filling the process chamber with air. The process may also include the step of opening the process chamber to receive a next batch of feedstock material.

The step of evacuating and/or removing air or surrounding atmosphere from a process chamber may include reducing and/or lowering a pressure within the process chamber. The evacuation may be to any suitable level, such as from atmospheric pressure to about 1,000 millibars absolute, to about 500 millibars absolute, to about 100 millibars absolute, to about 10 millibars absolute, and/or the like. The step of evacuating the air may also include flowing the air to or out an exhaust, a pollution control device, a reservoir, and/or the like.

The evacuating with the motive force device may be done with any suitable device, such as a vacuum pump, a liquid ring vacuum pump, dry seal pump, an ejector, an eductor, a regenerative blower, and/or the like.

The step of filing or flowing into the process chamber with inert gas from the reservoir may include allowing the inert gas to be drawn into the process chamber, such as to reduce the vacuum or reduced pressure within the process chamber from the step of evacuating. In the alternative, the step of filling may include supplying the inert gas under or with a positive pressure or motive force, such as with pressure in a reservoir. The reservoir may decrease and/or reduce in volume during filling of the process chamber with the inert gas from the reservoir.

The step of evacuating and/or removing the inert gas from the process chamber may include generally the aspects and/or characteristics described above with respect to the step of evacuating the air. The step of evacuating the inert gas may also include flowing the inert gas to or out an exhaust, a pollution control device, a reservoir, and/or the like.

The step of capturing the inert gas from the process chamber in the reservoir may include flowing the inert gas through a pipe, a channel, a duct, a conduit, a tubing, and/or the like. The step of capturing may include inflating or increasing a pressure within the reservoir.

The step of filling or flowing into the process chamber with air may include generally the aspects and/or characteristics described above with respect to the step of filling with the inert gas. The air may be drawn in from surroundings, pressurized with a mechanical device, supplied from a high pressure tank, and/or the like.

The method may also include the step of removing or catching particulate matter or contaminants from the inert gas with a particulate filter, such as in the line between the process chamber and the reservoir. The method may also include the step of removing or scavenging oxygen from the inert gas with an oxygen scavenger, such as chemically reacting or adsorbing the oxygen molecules with a substance or a material.

The method may also include the step of filling the process chamber with a portion of inert gas from an inert gas supply, such as with a cryogenic source of argon. The filling with the inert gas may be for initial or first use, such as during commissioning a system. The filling with the inert gas may also be for make up and/or replacement, such as for system losses and/or to reduce impurity levels in the inert gas within the process chamber.

The method may capture, recycle, or reuse any suitable portion or part of the inert gas from the process chamber, such as at least about 10 percent, at least about 25 percent, at least about 75 percent, at least about 85 percent, at least about 95 percent, at least about 98 percent, at least about 99 percent, and/or the like. The larger portion of recycle gas may reduce operating costs of the make up or fresh inert gas. In the alternative a certain amount of inert gas may be exhausted, such as for cooling, reducing impurities, and/or the like. According to one embodiment, an amount or quantity of inert gas is consumed on a generally constant basis to make up for system losses, such as flowing from an opening for adding or charging feedstock.

The inert gas may include argon, helium, nitrogen, xenon, other high temperature stable evaporated liquids, combinations of the above, and/or the like.

According to one embodiment, the method may include the step of at least partially deflating the reservoir, such as reducing a volume of the reservoir. The method may include the step of at least partially inflating the reservoir, such as increasing a volume of the reservoir. The inflating and/or deflating may include any suitable volume, such as the contents of the process chamber.

The method may also include the step of exhausting the air from the process chamber, such as to surroundings by drawing vacuum or reduced pressure. According to one embodiment, the method may include where the step of filling the process chamber with the inert gas from the reservoir occurs with a reduced pressure within the process chamber and excludes a mechanical motive force device. Allowing the vacuum to draw in the inert gas may provide a simple and less complex operation. In the alternative, the pressure from the reservoir supplies the inert gas to the process chamber. The inert gas from the reservoir may be supplied with a mechanical motive force device, as described above.

The filling or supplying the inert gas may also include a step of flooding or displacing another gas or vapor, such as instead of and/or in addition to filling a vacuum, The flooding may reduce or eliminate the need to evacuate the process chamber. In the alternative the filling or supplying the air may also include flooding, such as diluting and/or displacing the inert gas.

It will be apparent to those skilled in the art that various modifications and variations can be made in the disclosed structures and methods without departing from the scope or spirit of the invention. Particularly, descriptions of any one embodiment can be freely combined with descriptions or other embodiments to result in combinations and/or variations of two or more elements or limitations. Other embodiments of the invention will be apparent to those skilled in the art from consideration of the specification and practice of the invention disclosed herein. It is intended that the specification and examples be considered exemplary only, with a true scope and spirit of the invention being indicated by the following claims.

What is claimed is:

1. An apparatus for supplying an inert gas to a device suitable for melting high purity silicon, the apparatus comprising:
a process chamber comprising a load lock configuration for periodic charging of feedstock materials;
a reservoir in fluid communication with the process chamber; and
a motive force device in fluid communication with the process chamber and the reservoir.

2. The apparatus of claim 1, wherein the reservoir comprises a variable-volume structure.

3. The apparatus of claim 1, wherein the reservoir comprises a bladder.

4. The apparatus of claim 1, wherein the motive force device comprises a vacuum pump or a regenerative blower.

5. The apparatus of claim 1, further comprising an oxygen scavenger in a return line between the reservoir and the process chamber.

6. The apparatus of claim 1, further comprising a particulate filter in a supply line between the reservoir and the process chamber.

7. The apparatus of claim 1, further comprising an inert gas supply.

8. The apparatus of claim 1, further comprising an air inlet and an exhaust.

9. A method of operating an inert atmosphere of a device suitable for melting high purity silicon, the method comprising:
closing and evacuating air from a process chamber with a motive force device;
filling the process chamber with an inert gas from a reservoir;
transferring the feedstock into a melting region;
evacuating the inert gas from the process chamber with the motive force device;
capturing the inert gas from the process chamber in the reservoir;
filling the process chamber with air; and
opening the process chamber to receive a next batch of feedstock material.

10. The method of claim 9, further comprising removing particulate matter from the inert gas with a particulate filter.

11. The method of claim 9, further comprising removing oxygen from the inert gas with an oxygen scavenger.

12. The method of claim 9, further comprising filling the process chamber with a portion of inert gas from an inert gas supply.

13. The method of claim 9, wherein the inert gas comprises argon, helium, or nitrogen.

14. The method of claim 9, further comprising at least partially deflating the reservoir.

15. The method of claim 9, further comprising at least partially inflating the reservoir.

16. The method of claim 9, further comprising exhausting the air from the process chamber.

17. The method of claim 9, wherein the evacuating the air or evacuating the inert gas comprises a vacuum of less than about 1 millibar absolute.

18. The method of claim 9, wherein the filling the process chamber with the inert gas from the reservoir occurs with a reduced pressure within the process chamber and excludes a mechanical motive force device.

19. The method of claim 9, wherein the motive force device comprises a vacuum pump or a regenerative blower.
